(19) United States
(12) Patent Application Publication
(10) Pub. No.: US 2024/0112858 A1
(43) Pub. Date: Apr. 4, 2024

(54) MICRO DEVICE WITH SHEAR PAD

(71) Applicant: TEXAS INSTRUMENTS INCORPORATED, Dallas, TX (US)

(72) Inventor: Jeffrey A West, Dallas, TX (US)

(21) Appl. No.: 18/148,645

(22) Filed: Dec. 30, 2022

Related U.S. Application Data
(60) Provisional application No. 63/377,877, filed on Sep. 30, 2022.

(51) Int. Cl. H01F 41/04; H01F 27/28; H01F 27/29; H01F 27/32

(52) U.S. Cl. CPC H01F 41/041; H01F 27/2804; H01F 27/292; H01F 27/32; C23C 16/402

(57) ABSTRACT

An example method includes forming and patterning an etch assist layer on a first dielectric layer such that the etch assist layer is not over a first bond pad; forming and patterning a first photoresist layer on a second patterned conductive layer on the first dielectric, wherein the first photoresist layer is not over the first bond pad and etching the second dielectric layer to a depth of 5 to 15% of a thickness of the first dielectric layer and the second dielectric layer; etching the first dielectric layer and second dielectric layer using a second photoresist layer to a depth of 20 to 25%; and exposing the first bond pad by etching the first dielectric layer using a patterned third photoresist layer, such that an area of the dielectric layer exposed by the third opening adjacent to the bond pad is between 3-5 μm thick.

### CROSS-REFERENCE TO RELATED APPLICATIONS

This application claims the benefit under 35 U.S.C. § 119(e) to co-owned U.S. Provisional Patent Application Ser. No. 63/377,877, filed Sep. 30, 2022, which is hereby incorporated by reference in its entirety herein.

### TECHNICAL FIELD

This relates generally to micro-devices, and more particularly to test functionality in micro-electrical devices.

### BACKGROUND

Electrical and electronic devices for harsh environments have significant test requirements to avoid operational failure as much as possible. Examples of such harsh environments are automotive, military, and aeronautical uses. These harsh environments increase the possibility of device failures due to vibration, thermal stresses, and other forces. In addition to the additional stresses on the devices, these environments often require a high level of durability to avoid safety problems.

To address these harsh environment and safety issues, device customers often require testing regimes to ensure that manufacturing processes stay within prescribed tolerances. With micro-electrical and microelectronic devices (collectively “micro devices”), a structure that is of concern are wire bonds. In examples, wire bonds use balls of conductive material (e.g., gold) that are physically bonded to bond pads of conductive material (e.g., aluminum). The wire bonding equipment applies heat and vibrational energy to create the bond between the balls and the bond pads. Wire bonding between two micro devices generally starts by briefly heating the end of a wire to just above the melting point of the material comprising the wire to form a surface-tension induced ball, which cools into a solid state and is physically pressed against a preheated bond pad on a micro device while vibrational energy is simultaneously applied to the wire to provide frictional heat to the interface between pad and wire tip to achieve a thermo-mechanical bond. The wire is then sheared off just above the bonded ball, leaving a ball and small remnant of wire bonded to the pad. The bonder then similarly creates a ball on the sheared-off wire and bonds it to the bond pad of another micro device. The bonder guides the bonded wire back to the previously formed bonded ball on the original pad and applies heat and vibrational energy to the wire as it presses it into the previously bonded ball to form what is called a stitch bond. The bonder then shears off the wire near the stitch bond and repeats this cycle between the next two pads to be coupled between micro devices, repeating until all desired pads between micro devices are coupled.

The strength of the wire bonds to the micro device bond pads is a reliability concern. Insufficient bonding pressure and/or contamination are some of the problems that may occur. To ensure adequate bonds, shear testing may be required. In shear testing, devices are sampled from the manufacturing process after ball bonding. A shear blade is lowered to the side of the ball, then laterally moved into the bond at which point the force required to shear through the bond is reported. If the force is within specifications, the test is passed. If not, the test is failed, and manufacturing must be halted to determine what caused the inadequate ball bond. Generally, bond pads are recessed relative to the dielectric surface that provides passivation for the micro device. To facilitate shear testing, enlarged openings are provided at selected bond pads that allow room for the shear blade to be lowered far enough to contact the side of the ball. The balls are on the order of 4-10 microns high after compression. To be able to shear through the ball, there can be no structures thicker than a few microns within the enlarged openings. Otherwise, the blade will shear through the wire instead of the ball, giving erroneous test results.

### SUMMARY

In accordance with an example, a method includes forming a first patterned conductive layer on a substrate, the first patterned conductive layer including a first bond pad and forming a first dielectric layer on the first patterned conductive layer. The method also includes forming an etch assist layer on the first dielectric layer and patterning the etch assist layer such that the etch assist layer is not over the first bond pad. The method also includes forming a second dielectric layer on the first dielectric layer and the etch assist layer and forming a second patterned conductive layer on the dielectric layer. The method also includes forming and patterning a first photoresist layer on the second patterned conductive layer, wherein the first photoresist layer does not cover the first bond pad and etching the dielectric layer using the first photoresist layer as a mask to a depth of 5 to 15% of a thickness of the first dielectric layer and the second dielectric layer. The method also includes forming and patterning a second photoresist layer having a pattern for a second opening to the first bond pad and etching the first dielectric layer and second dielectric layer using the second photoresist layer as a mask to a depth of 20 to 25% of an exposed portion of the first dielectric layer and second dielectric layer. The method also includes forming and patterning a third photoresist layer, wherein the third photoresist layer has a third opening that is smaller than the first opening and larger than the second opening and etching the first dielectric layer using the third photoresist layer as a mask, such that the first bond pad is exposed in the form of the second opening and such that an area of the dielectric layer exposed by the third opening but not exposed by the second opening is between 3-5 μm thick.

### BRIEF DESCRIPTION OF THE DRAWINGS

FIGS. 1A and 1B (collectively “FIG. 1”) are a top view and side view, respectively, of an example “shear pad.”

FIG. 2 is a plan view of an example micro-electrical device.

FIG. 3 is a cross section view of the transformer of FIG. 2 along the cut line indicated in FIG. 2.

FIGS. 4A-L (collectively “FIG. 4”) are side view diagrams showing an example process for fabricating an example device having a shear pad.

FIGS. 5A and 5B (collectively “FIG. 5”) is a flow chart showing a process summarizing features of the process described in FIG. 4.

### DETAILED DESCRIPTION

In the drawings, corresponding numerals and symbols generally refer to corresponding parts unless otherwise indicated. The drawings are not necessarily drawn to scale.

In this description, the term “coupled” may include connections made with intervening elements, and additional elements and various connections may exist between any elements that are “coupled.” Also, as used herein, the terms “on,” “over,” and “cover” may include layers or other elements where intervening or additional elements are between an element and the element that it is “on,” “over,” or “covering.”

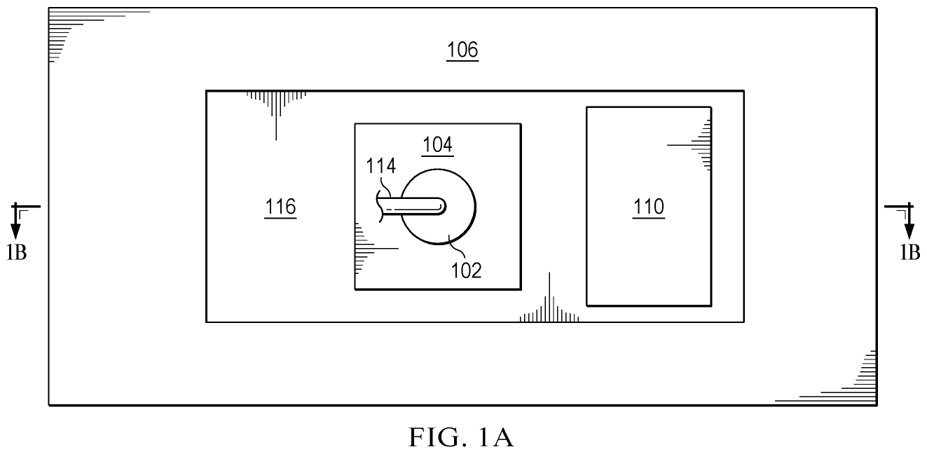

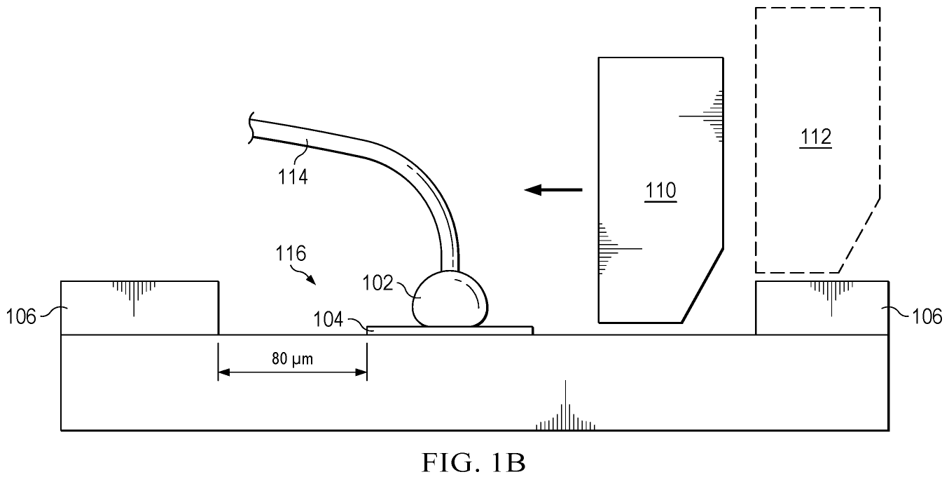

FIGS. 1A and 1B (collectively “FIG. 1”) are a top view and a side view, respectively, of an example “shear pad.” A “shear pad” is a bond pad configured to facilitate wire bond shear force testing. Polyimide layer 106 is about 4-10 μm thick in this example. For bond pads that are not configured as shear pads (not shown), the opening in polyimide layer 106 is within five to ten microns of the bond pad. However, for a shear pad, this would be unacceptable because polyimide layer 106 would not allow the shear test blade 110 to go down low enough for proper contact through the wire 114 near the ball bond 102 as shown by the shadow shear blade 112 in FIG. 1B. Shadow shear blade 112 would contact wire 114 above the ball, and thus would provide erroneous data, which may lead to unnecessary waste due to scrapping devices that should have passed this test. To avoid this problem, opening 116 in polyimide layer 106 is widened in at least two directions to allow room for shear test blade 110 to be lowered to a proper height adjacent to the ball bond 102 and then to laterally shear off the bond without colliding into polyimide on the backside of the bond. In this example, the edge of opening 116 is at least 80 μm away from bond pad 104 in the lateral direction relative to the page. This type of shear pad allows for accurate test results. However, some micro devices have an inorganic dielectric passivation layer for which the surface of bond pad 104 is recessed by more than 5 μm from the passivation layer surface. With these devices, a more complex integration scheme is required to create an adequate shear window.

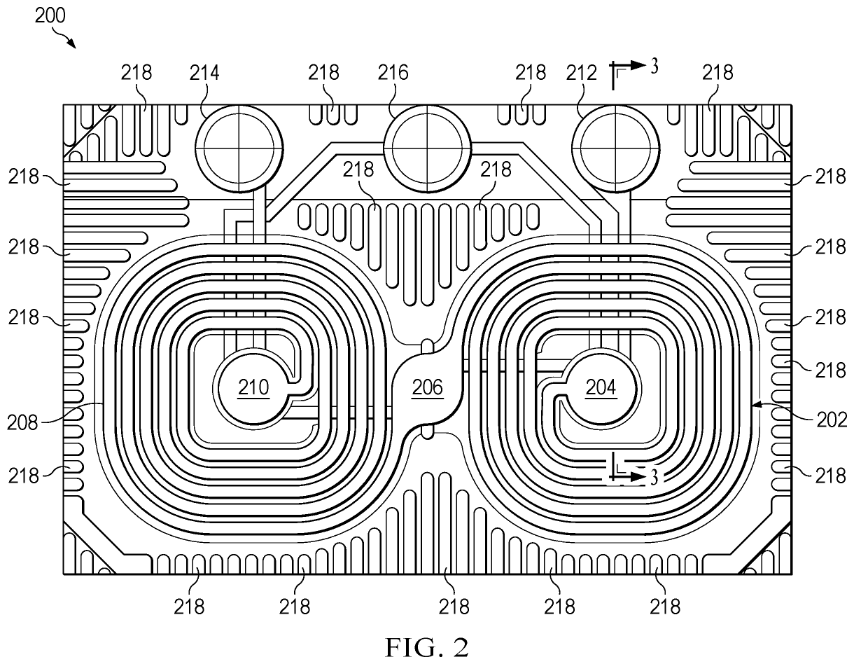

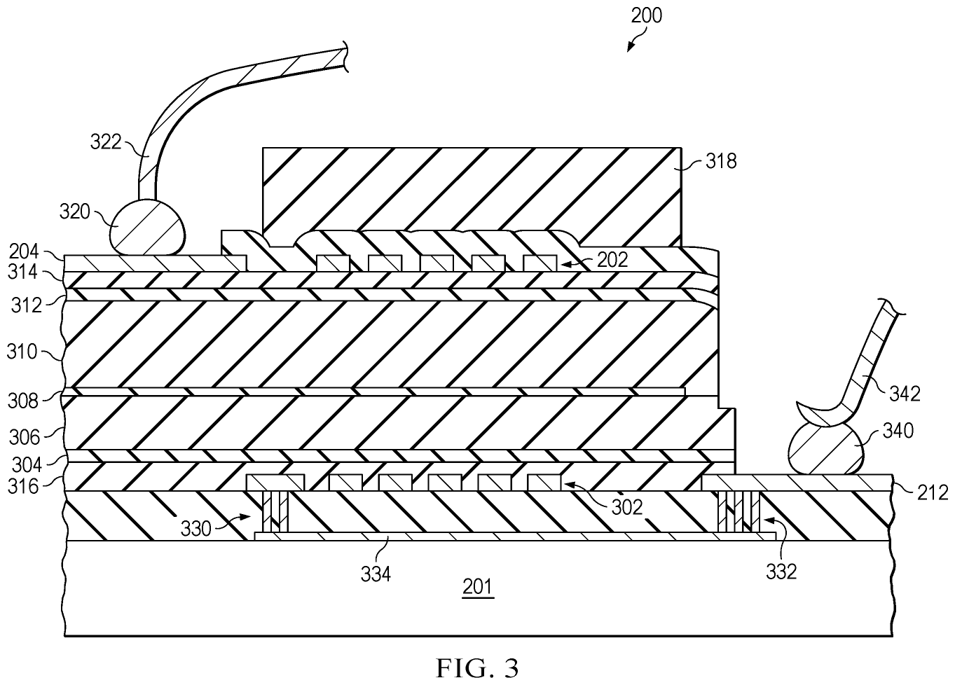

FIG. 2 is a plan view of an example micro-electrical device. Transformer 200 is an example passive micro-electrical device. In some environments, sensitive semiconductor devices must operate along with higher voltage devices. For example, in the automotive field, battery packs in electric vehicles may operate at up to 800V or more, but lower voltage processors must monitor and control the operation of the vehicle. Devices like transformer 200 are used to isolate the high voltage devices from the low voltage devices while passing necessary signals between them. In addition, transformers are used to isolate circuits to avoid passing unwanted signals. In the example of transformer 200, first coil 202 turns counterclockwise from first bond pad 204 to first center tap bond pad 206. Second coil 208 turns clockwise from first center tap bond pad 206 to second bond pad 210. A matching set of coils (not shown) is underneath first coil 202 and second coil 208. Third bond pad 212 couples to the coil that matches first coil 202 and fourth bond pad 214 couples to the coil that matches second coil 208. Second center tap bond pad 216 couples to the center tap between the lower coils. In this example, the high voltage inputs are coupled to first coil 202 and second coil 208. Therefore, this is called the high voltage level. The lower coils are thus called the low voltage level. Field strips 218 are provided in the areas where the coils and bond pads are not. Field strips 218 in the low voltage level minimize stray fields and help to relieve stresses that may cause cracking. As explained further below, there is a thick insulating layer between the high voltage level and the low voltage level. A portion of this thick insulating layer remains over the lower voltage metal to provide passivation and prevent lateral breakdown between the high voltage coils and the low voltage field strips. The bond pad surface of third bond pad 212, fourth bond pad 214 and second center tap bond pad 216 is recessed by less than 6 μm from the surrounding passivation layer surface to make it possible to shear bonds made to these pads.

FIG. 3 is a cross section view of transformer 200 along the cut line indicated in FIG. 2. The cut line of FIG. 2 does not go through all of the elements described in FIG. 3. Specifically, the connections between third bond pad 212 and third coil 302 would not line up with the cut line of FIG. 2. However, for completeness of explanation, these components are included in FIG. 3. First coil 202 is separated from third coil 302 by silicon oxynitride layer 304, silicon dioxide layer 306, silicon oxynitride layer 308, silicon dioxide layer 310, silicon oxynitride layer 312, and silicon nitride layer 314. The total thickness of these layers is approximately 17 μm in this example. Insulating layer 316, which is a combination of silicon dioxide, silicon oxynitride, and silicon nitride layers, covers first coil 202. Polyimide layer 318 provides additional protection by keeping encapsulation mold compound away from regions of extreme high electric fields. Ball bond 320 is coupled to first bond pad 204, and first bond wire 322 is coupled to ball bond 320. Vias 330, vias 332 and first metal layer 334 couple third bond pad 212 to third coil 302. First metal layer 334 is formed on substrate 201. Stitch bond 340 is coupled to third bond pad 212, and second bond wire 342 is coupled to stitch bond 340.

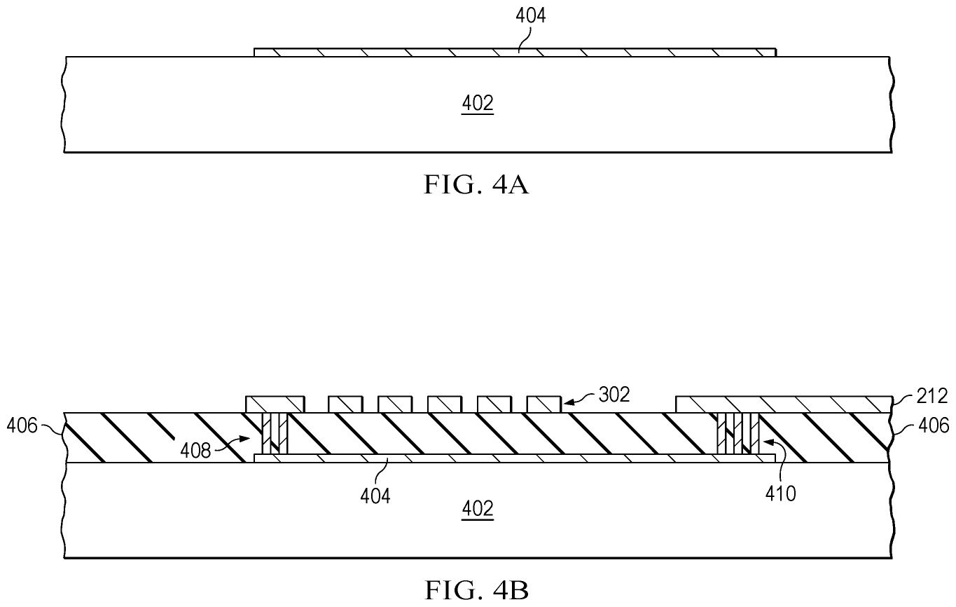

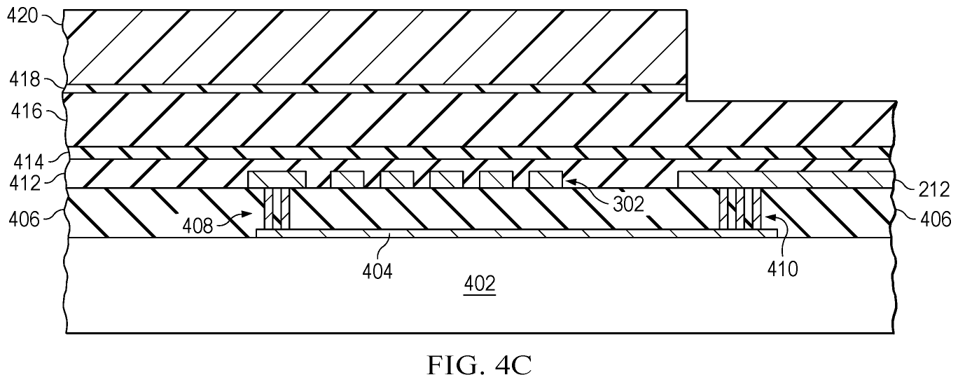

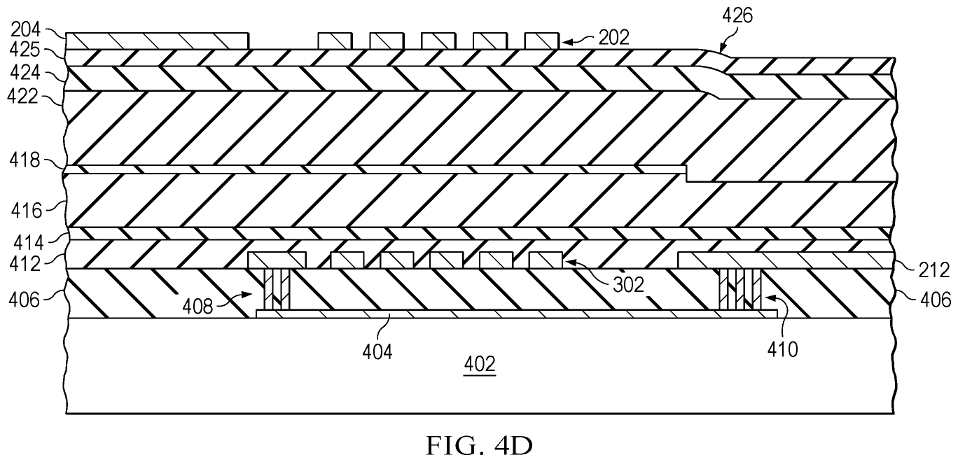

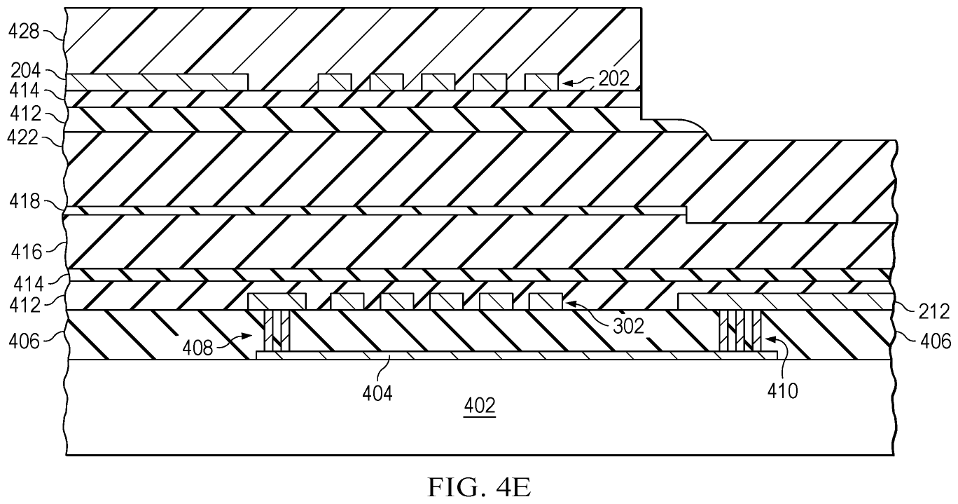

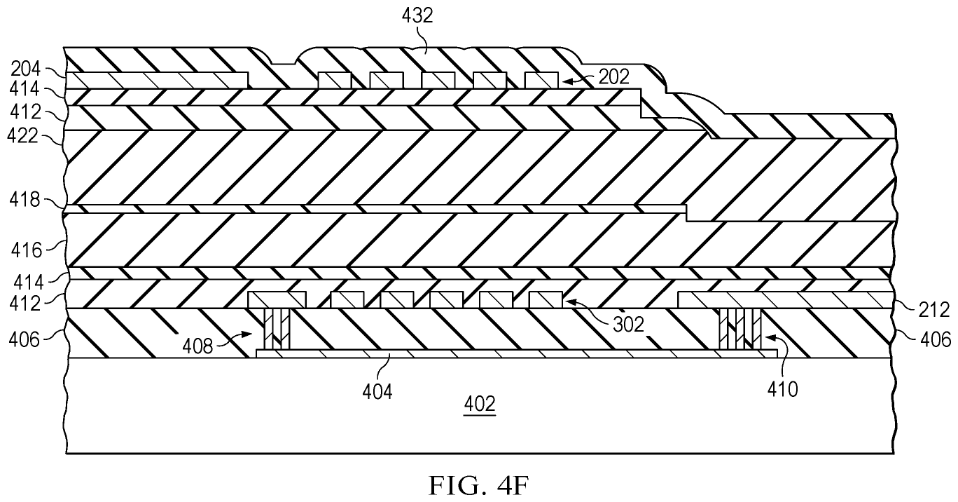

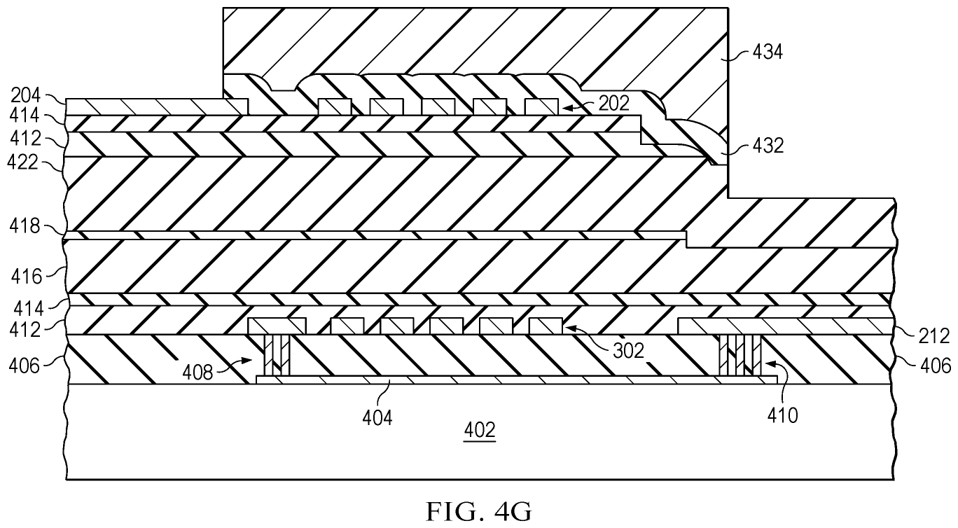

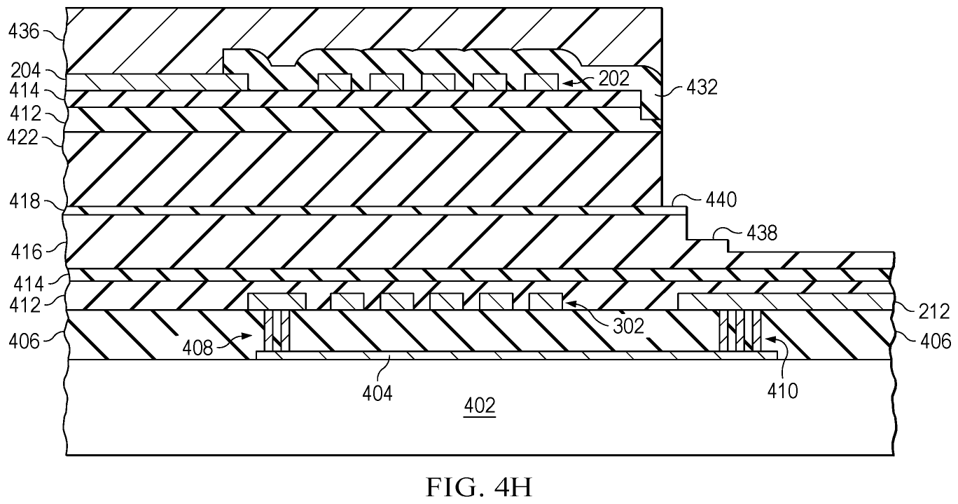

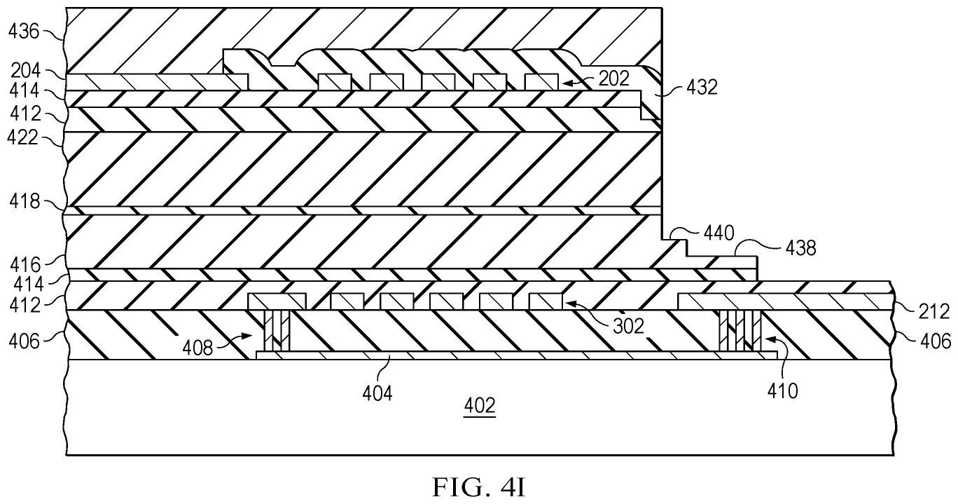

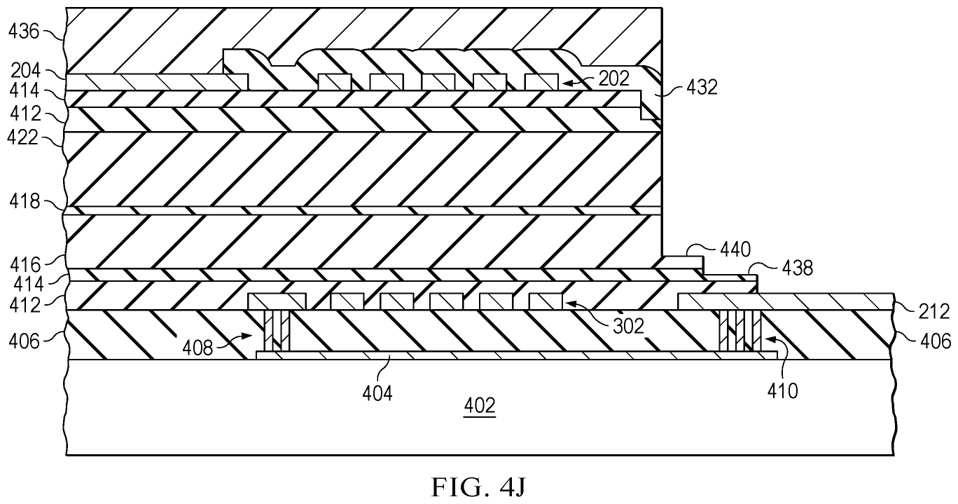

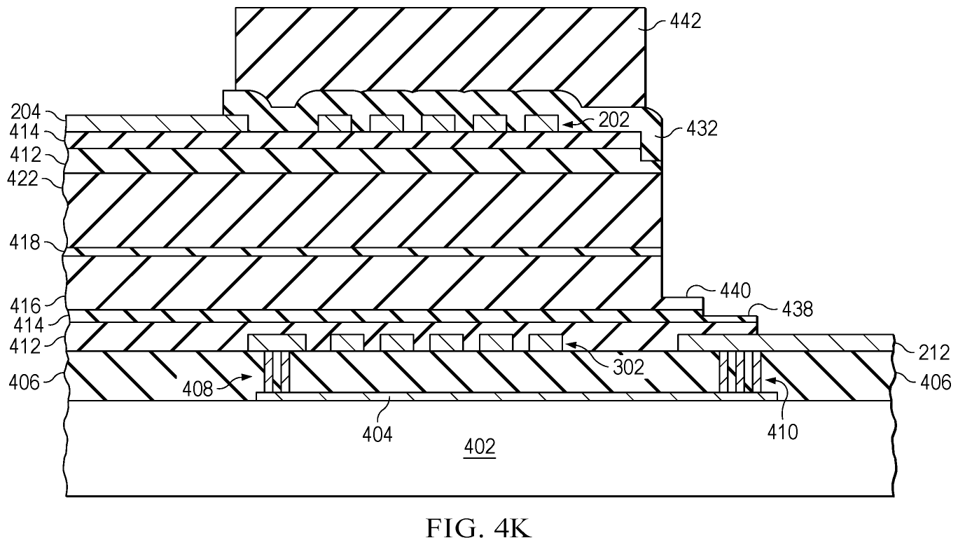

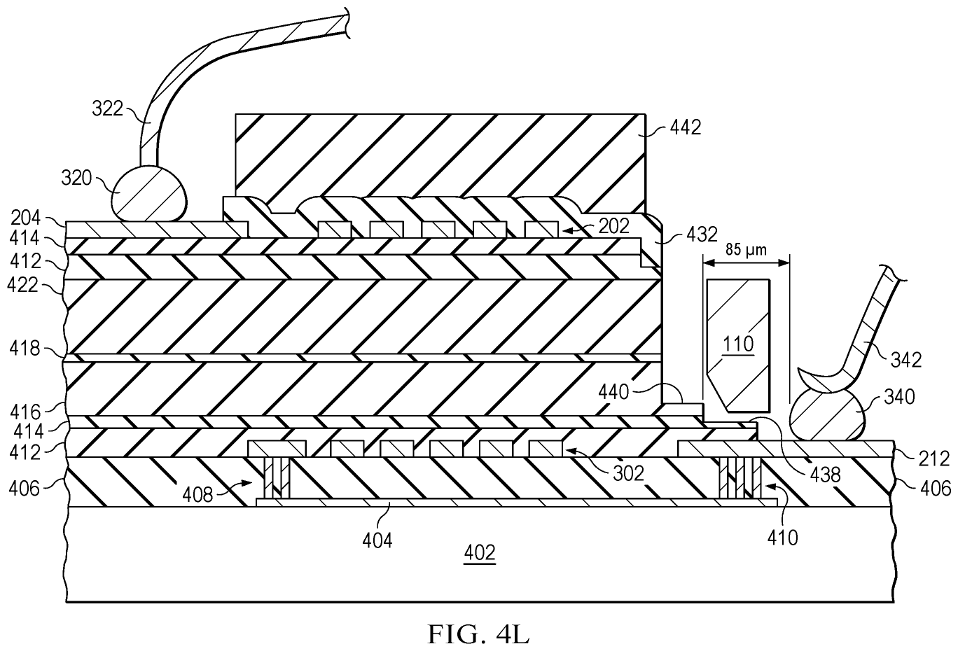

The functions of silicon oxynitride layer 304, silicon dioxide layer 306, silicon oxynitride layer 308 silicon dioxide layer 310, silicon oxynitride layer 312, and silicon nitride layer 314 are more fully explained below with regard to FIG. 4. However, to explain the difficulty of using third bond pad 212 as a shear pad, the function of silicon oxynitride layer as an etch stop in etching the thick layers above it is important. To open third bond pad 212, silicon dioxide layer 306 and silicon dioxide layer 310 must be etched. These thick layers require a robust etch stop layer. Thus, silicon oxynitride layer 304 is 1 μm thick in this example. In addition, silicon nitride layer 314 above third bond pad 212 is 5kÅ to 8kÅ thousand angstroms thick. Even if the opening for third bond pad 212 is expanded above silicon oxynitride layer 304, silicon oxynitride layer 312 and the portion of silicon nitride layer 314 are too thick for a shear test blade to properly contact stitch bond 340. Therefore, a simple shear pad window is not possible for the low voltage bond pads like third bond pad 212 and it is necessary to provide a process and structure that allows for the necessary opening to use one or more of the low voltage bond pads as a shear test bond pad.

FIGS. 4A-L (collectively “FIG. 4”) are side view diagrams showing an example process for fabricating an example device having a shear pad. FIG. 4A shows a substrate 402 with a first patterned metal layer 404 deposited using sputtering, electroplating, and/or chemical vapor deposition (CVD) to approximately 0.5 μm thick. In this example, substrate 402 is a crystalline silicon substrate approximately 700 μm thick. In an example, CVD forms a thin insulating layer (not shown) such as a silicon dioxide layer having a thickness of approximately 0.85 μm on substrate 402 before depositing first patterned metal layer 404. FIG. 4B shows a first insulating layer 406 formed by CVD and planarized by, for example, chemical mechanical polishing (CMP) above first patterned metal layer 404 to a thickness of approximately 0.7 μm. After CMP, an additional 2.3 μm plasma enhanced CVD (PECVD) TEOS layer is deposited to complete first insulating layer 406. In this example, about 67% of first insulating layer 406 is low stress silicon dioxide layer formed by deposition from tetraethyl orthosilicate (TEOS). In this example, low stress TEOS is formed at a pressure of approximately 3 Torr and high stress TEOS is formed at a pressure of approximately 3.2 Torr.

First vias 408 and second vias 410 are formed by etching first insulating layer 406 and filling the openings with a suitable conductor such as tungsten. A second layer metal is deposited or sputtered to a thickness of 1.3-1.8 μm. The second layer metal in this example is a stack of titanium, titanium nitride, aluminum, and titanium nitride. The second metal layer is photolithographically patterned then etched to form third coil 302 and third bond pad 212. The other coils and bond pads at the low voltage level are also formed at this time but are not shown in FIG. 4. In addition, field strips (not shown) in this metal layer are also formed with this step in this example.

FIG. 4C shows that a composite layer 412 including a silicon nitride layer, a silicon oxynitride layer and a silicon dioxide layer are formed on third coil 302 and third bond pad 212 using CVD. The composite layer is planarized and CVD forms an etch stop layer 414 including silicon oxynitride on composite layer 412. CVD forms first dielectric layer 416 on etch stop layer 414. In this example, first dielectric layer is formed with alternating layers of high stress TEOS and low stress TEOS to reduce the susceptibility to cracking during subsequent processing. First dielectric layer 416 is approximately 9.6 μm in this example but can range from 1 to 15 μm. CVD forms an etch assist layer 418 including silicon oxynitride. A first photoresist layer 420 is formed and patterned on etch assist layer 418. Plasma etching removes the exposed portion of etch assist layer 418 and, due to over-etching to ensure removal of etch assist layer 418, also removes a portion of first dielectric layer 416 as shown in FIG. 4C. As is further explained hereinbelow, after patterning, etch assist layer 418 introduces surface topography that allows for alignment of subsequent masks in the process.

FIG. 4D shows the steps for formation of the first coil 202 and first bond pad 204. CVD forms second dielectric layer 422 by alternately forming high stress TEOS layers and low stress TEOS layers. Second dielectric layer 422 is approximately 5.7 μm thick but can range from 2 to 8 μm. CVD forms a sealing layer, which is a combination of silicon nitride layer 424 and silicon oxynitride layer 425 with a total thickness of approximately 1 μm but can range from 0.5 to 2 μm. CVD and/or sputtering forms a layer of aluminum approximately 3 μm thick on silicon oxynitride layer 425, which is patterned and etched to form first bond pad 204 and first coil 202, which is concentric with third coil 302. This step uses the non-planarity caused by etch assist layer 418. Without this non-planarity, the top surface of the aluminum layer would be flat with no way for the photolithography tool to align the pattern to the underlying layers. In addition, the openings in etch assist layer define the openings for the low voltage bond pads including shear pads as is further described below. Thus, first coil 202 and third coil 302 can be properly aligned to provide concentric coils utilizing the topography 426 resulting from the patterning of etch assist layer 418.

FIG. 4E shows a second photoresist layer 428 patterned so that the end of second photoresist layer 428 is approximately 14 μm from the nearest coil of first coil 202. However, this distance can range from 10-25 μm. Using second photoresist layer 428, the exposed portion of the sealing layer, silicon nitride layer 424 and silicon oxynitride layer 425, and approximately 1.6 μm of second dielectric layer 422 are removed using plasma etching. Second photoresist layer 428 is patterned so that this etch occurs at lower voltage bond pads that are desired to be shear pads, and not at other lower voltage bond pads. In an example, in some configurations, an etch is performed to begin defining scribe lanes between devices in a wafer. This scribe line etch can be combined with the etch illustrated in FIG. 4E for efficiency.

FIG. 4F shows a step for forming a protective layer on the structure of FIG. 4E. In FIG. 4F, second photoresist layer 428 is removed and a protective layer 432 is formed. In an example, protective layer 432 includes high-density plasma (HDP) CVD deposited silicon dioxide, high stress TEOS and silicon oxynitride. Protective layer 432 is approximately 3.2 μm thick.

FIG. 4G shows a step for forming an opening to first bond pad 204 and beginning to form the opening to third bond pad 212. A third photoresist layer 434 is deposited and patterned on protective layer 432. Of note, the edge of second photoresist layer over third bond pad 212 is approximately 9 μm to the right (in the perspective of the page) of etch assist layer 418. As explained further hereinbelow, this 9 μm gap ultimately results in defining a region of dielectric thickness with sufficiently low topography relative to the exposed surface of third bond pad 212 to enable shearing of the eventual wire bond to third bond pad 212. Protective layer 432 is etched to open first bond pad 204. Because first bond pad 204 is a different material from the materials of protective layer 432, the etching stops at first bond pad 204. In an example, the etchant used in this step is a plasma of CF4+CHF3+Ar. However, in the area above third bond pad 212, the etchant will remove all of protective layer 432 and etch approximately 1.1 μm into second dielectric layer 422. In an example, this etch step removes approximately 20-25% of the combination of protective layer, second dielectric layer 422, first dielectric layer 416, etch stop layer 414, and composite layer 412.

FIG. 4H shows a step where a fourth photoresist layer 436 is formed and patterned on protective layer 432 and first bond pad 204. Fourth photoresist layer 436 is 15 μm thick, for example. Thus, fourth photoresist layer 436 is thick enough to withstand etching through the dielectric layers above third bond pad 212, which includes, the remainder of second dielectric layer 422, first dielectric layer 416, etch stop layer 414, and composite layer 412 to expose third bond pad 212. FIG. 4H shows etching through second dielectric layer 422 using a low selectivity etchant such as C5F8+O2. Then an etchant such as C4F8+O2 that is selective to the material in etch assist layer 418 is used, then the non-selective etchant is used to etch through most of first dielectric layer 416, and then returns to a selective etch to stop in layer 414. Because of the prior etching steps of FIG. 4E, etching protective layer 432 as in FIG. 4G, and the effect of etching etch assist layer 418 as in FIG. 4C, a two-step structure forms with first step 438 and second step 440. Specifically, the etching of the exposed portion of protective layer 432, which is comprised partly of silicon oxynitride, is slower than the etching of second dielectric layer 422, which is comprised of silicon dioxide. In addition, when the etching of second dielectric layer 422 reaches etch assist layer 418, the etching is slowed by etch assist layer 418 but continues at the normal rate into first dielectric layer 416. The heights of first step 438 and second step 440 are determined by the difference in etch rates of the respective materials and, of importance, by the prior removal of layer 418 during the etch of FIG. 4C.

FIG. 4I shows a continuation of the etching of first dielectric layer 416 and where the portion of etch stop layer 414 above third bond pad 212 is removed. FIG. 4J shows a continuation of etching first dielectric layer 416, etch stop layer 414 and composite layer 412. As shown in FIG. 4J, this step exposes third bond pad 212. Of importance, the etch continues at first step 438 and second step 440 such that first step 438 is into etch stop layer 414. Thus, the portion of composite layer 412 and etch stop layer 414 at first step 438 is significantly thinned to 3 to 5 μm, as opposed to 6 μm or more as in FIG. 3.

FIG. 4K shows the formation of polyimide layer 442. An uncured photo-sensitive polyimide layer is deposited using a spin-coat technique. Using a standard binary mask, portions of the polyimide are exposed to broad spectrum light which causes the material to cross-link in such a way that during subsequent exposure to chemical developer causes the illuminated regions to remain and the unilluminated regions to dissolve away.

FIG. 4L shows ball bond 320 is coupled to first bond pad 204, and first bond wire 322 is coupled to ball bond 320. In addition, stitch bond 340 is coupled to third bond pad 212, and second bond wire 342 is coupled to stitch bond 340. Because composite layer 412 and etch stop layer 414 are significantly thinned at first step 438, a shear blade 110 has an area approximately 85 μm wide from second step 440 to stitch bond 340, thus allowing third bond pad 212 to serve as a shear pad. Of note, shear test blade 110 moves in a direction normal to the page. The position of shear test blade 110 in FIG. 4L is only to illustrate its position relative to stitch bond 340.

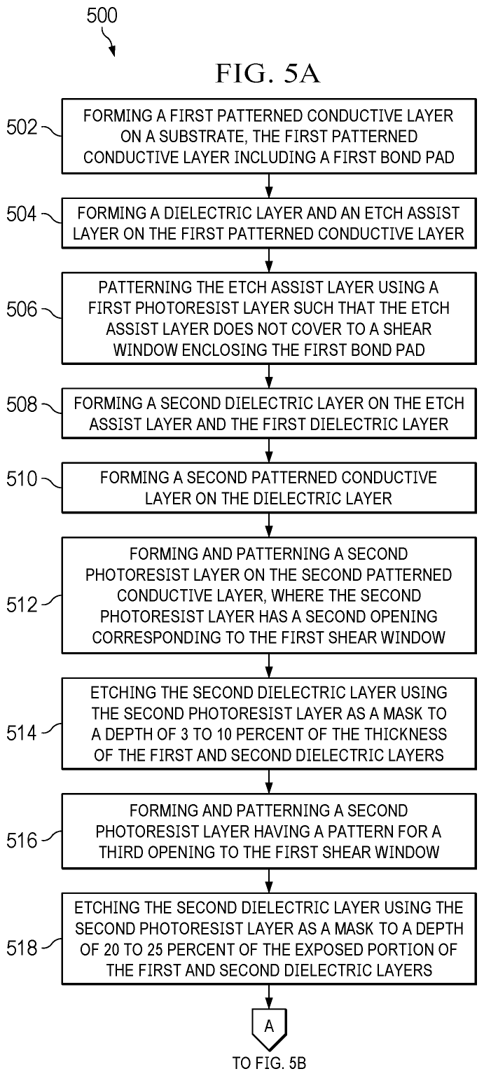

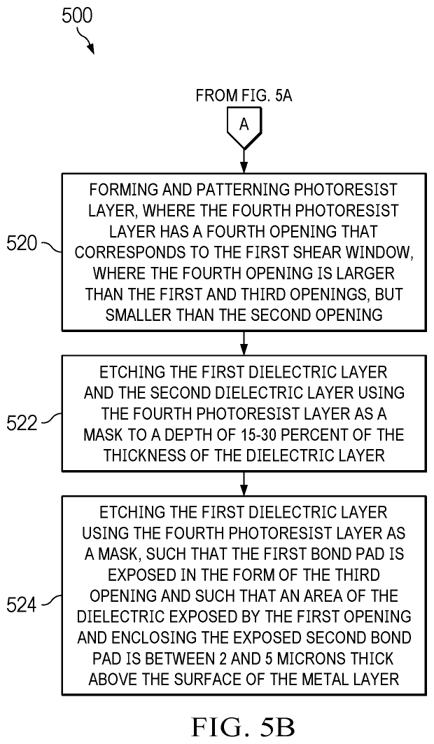

FIGS. 5A and 5B (collectively “FIG. 5”) is a flow chart showing a process 500 summarizing features of the process described in FIG. 4. Step 502 is forming a first patterned conductive layer on a substrate, the first patterned conductive layer including a first bond pad. An example of a first patterned conductive layer is third coil 302 and third bond pad 212 (FIG. 4L). Step 504 is forming a dielectric layer and an etch assist layer on the first patterned conductive layer. An example of the dielectric layer is first dielectric layer 416. An example of an etch assist layer is etch assist layer 418 (FIG. 4L). Step 506 is patterning the etch assist layer using a first photoresist layer such that the etch assist layer does not cover to a shear window above the first bond pad. An example of this is illustrated in FIG. 4C. An example of the first photoresist layer is first photoresist layer 420 (FIG. 4C). Step 508 is forming a second dielectric layer on the etch assist layer and the first dielectric layer. An example of a second dielectric layer is second dielectric layer 422 (FIG. 4D). Step 510 is forming a second patterned conductive layer on the dielectric layer. An example of a second patterned conductive layer is first coil 202 and first bond pad 204 (FIG. 4L). Step 512 is forming and patterning a second photoresist layer on the second patterned conductive layer, wherein the second photoresist layer has a second opening corresponding to the first shear window. An example of a second photoresist layer is second photoresist layer 428 (FIG. 4E). Step 514 is etching the second dielectric layer using the second photoresist layer as a mask to a depth of 3 to 10% of the thickness of the first and second dielectric layers. An example of this step is illustrated in FIG. 4E. Step 516 is forming and patterning a third photoresist layer having a pattern for a third opening to the first shear window. An example of a third photoresist layer is third photoresist layer 434 (FIG. 4G). Step 518 is etching the second dielectric layer using the third photoresist layer as a mask to a depth of 20 to 25% of the exposed portion of the first and second dielectric layers. An example of this step is illustrated in FIG. 4G. Step 520 is forming and patterning a fourth photoresist layer, wherein the fourth photo resist layer has a fourth opening that corresponds to the first shear window, wherein the fourth opening is larger than the first and third openings, but smaller than the second opening. An example of a fourth photoresist layer is fourth photoresist layer 436 (FIG. 4H). Step 522 is etching the first dielectric layer and the second dielectric layer using the fourth photoresist layer as a mask to a depth of 15-30% of the thickness of the dielectric layer. An example of this step is illustrated in FIG. 4H. Step 524 is etching the first dielectric layer using the fourth photoresist layer as a mask, such that the first bond pad is exposed in the form of the third opening and such that an area of the dielectric exposed by the first opening and enclosing the exposed second bond pad is between 2 and 5 microns thick above the surface of the metal layer. An example of this step is illustrated in FIGS. 41 and 4J.

Modifications are possible in the described examples, and other examples are possible, within the scope of the claims.

What is claimed is:

1. A method comprising:
forming a first patterned conductive layer on a substrate, the first patterned conductive layer including a first bond pad;
forming a first dielectric layer on the first patterned conductive layer;
forming an etch assist layer on the first dielectric layer;
patterning the etch assist layer such that the etch assist layer is not over the first bond pad;
forming a second dielectric layer on the first dielectric layer and the etch assist layer;
forming a second patterned conductive layer on the dielectric layer;
forming and patterning a first photoresist layer on the second patterned conductive layer, wherein the first photoresist layer does not cover the first bond pad;
etching the dielectric layer using the first photoresist layer as a mask to a depth of 5 to 15% of a thickness of the first dielectric layer and the second dielectric layer;
forming and patterning a second photoresist layer having a pattern for a second opening to the first bond pad;
etching the first dielectric layer and second dielectric layer using the second photoresist layer as a mask to a depth of 20 to 25% of an exposed portion of the first dielectric layer and second dielectric layer;
forming and patterning a third photoresist layer, wherein the third photoresist layer has a third opening that is smaller than the first opening and larger than the second opening; and
etching the first dielectric layer using the third photoresist layer as a mask, such that the first bond pad is exposed in the form of the second opening and such that an area of the dielectric layer exposed by the third opening but not exposed by the second opening is between 3-5 μm thick.

2. The method of claim 1, wherein the first dielectric layer includes silicon dioxide, and the second dielectric layer includes silicon dioxide.

3. The method of claim 2, wherein the etch assist layer includes nitrides of silicon.

4. The method of claim 1, wherein the first patterned conductive layer includes a first coil, the second patterned conductive layer includes a second coil, and the first coil and the second coil are concentric and aligned with each other.

5. The method of claim 1, wherein the dielectric layer includes silicon dioxide.

6. The method of claim 1, further comprising:
forming a protective layer on the second patterned conductive layer after the etching the dielectric layer using the first photoresist layer.

7. The method of claim 6, wherein the second photoresist layer includes a fourth opening corresponding to a second bond pad in the second patterned conductive layer and wherein the etching the dielectric layer using the second photoresist layer provides an opening in the protective layer exposing the second bond pad.

8. The method of claim 1, further comprising:
bonding a ball bond to the first bond pad.

9. A method comprising:
forming a first patterned conductive layer on a substrate, the first patterned conductive layer including a first bond pad;
forming a composite layer on the first patterned conductive layer;
forming an etch stop layer on the composite layer;
forming a first dielectric layer on the first patterned conductive layer;
forming an etch assist layer on the first dielectric layer;
patterning the etch assist layer such that the etch assist layer has an edge;
forming a second dielectric layer on the etch assist layer and exposed portions of the first dielectric layer;
forming a second patterned conductive layer on the second dielectric layer;
forming and patterning a first photoresist layer on the second patterned conductive layer, wherein the first photoresist layer does not cover the first bond pad;
etching the second dielectric layer using the first photoresist layer as a mask to a depth of 5 to 15% of a thickness of the first dielectric layer and the second dielectric layer;
forming and patterning a second photoresist layer having a pattern for a second opening to the first bond pad, wherein the second opening is a selected distance from the edge;
etching the first dielectric layer and the second dielectric layer using the second photoresist layer as a mask to a depth of 20 to 25% of an exposed portion of the second dielectric layer;
forming and patterning a third photoresist layer, wherein the third photoresist layer has a third opening that is smaller than the first opening and larger than the second opening; and
etching the first dielectric layer, the etch stop layer, and the composite layer using the third photoresist layer as a mask, such that the first bond pad is exposed in the form of the second opening and such that an area of the etch stop layer and the composite layer exposed by the third opening but not exposed by the second opening is between 3 to 5 μm thick.

10. The method of claim 9, wherein the first dielectric layer and the second dielectric layer are silicon dioxide, and the etch assist layer includes silicon oxynitride.

11. The method of claim 9, wherein the first patterned conductive layer includes a first coil, the second patterned conductive layer includes a second coil, and the first coil and the second coil are concentric and aligned with each other.

12. The method of claim 9, wherein the first dielectric layer and the second dielectric layer include silicon dioxide.

13. The method of claim 9, further comprising:
forming a protective layer on the second patterned conductive layer after the etching the second dielectric layer using the first photoresist layer.

14. The method of claim 13, wherein the second photoresist layer includes a fourth opening corresponding to a second bond pad in the second patterned conductive layer and wherein the etching the dielectric layer using the second photoresist layer provides an opening in the protective layer exposing the second bond pad.

15. The method of claim 9, further comprising:
bonding a ball bond to the first bond pad.

16. A device comprising:
a first patterned conductive layer on a substrate, the first patterned conductive layer including a first bond pad;
a dielectric layer on the first patterned conductive layer, wherein the dielectric layer an opening exposing the first bond pad and a portion adjacent the opening having a thickness between 3 to 5 μm thick; and
a second patterned conductive layer on the dielectric layer.

17. The device of claim 16, wherein the dielectric layer includes:
a first dielectric layer;
an etch assist layer on the first dielectric layer; and
a second dielectric layer on the etch assist layer.

18. The device of claim 17, wherein the first dielectric layer and the second dielectric layer are silicon dioxide, and the etch assist layer includes silicon oxynitride.

19. The device of claim 17, wherein the first patterned conductive layer includes a first coil, the second patterned conductive layer includes a second coil, and the first coil and the second coil are aligned with each other.

20. The device of claim 16, further comprising:
a ball bond bonded to the first bond pad.
